(19) United States
(12) Patent Application Publication
(10) Pub. No.: US 2016/0192541 A1
(43) Pub. Date: Jun. 30, 2016

(54) ELECTRONIC DEVICE CABINET AND A DISSIPATION BOARD

(71) Applicant: Whirlpool S.A., Sao Paulo (BR)

(72) Inventors: Rafael Burg Rech, Joinville (BR); Ede Carlos James Caldeira, Joinville (BR); Lucas Mondardo Cunico, Joinville (BR)

(73) Assignee: WHIRLPOOL S.A., Sao Paulo (BR)

(21) Appl. No.: 14/864,108

(22) Filed: Sep. 24, 2015

(30) Foreign Application Priority Data
Dec. 26, 2014 (BR) 20 2014 032719-9

(51) Int. Cl. H05K 7/20; H05K 7/14

(52) U.S. Cl. CPC H05K 7/20509; H05K 7/1418

(57) ABSTRACT

An electronic device cabinet comprising a housing and a printed-circuit board positioned in an internal area of the housing and defining a dissipation chamber. The dissipation chamber is formed between a first surface of the printed-circuit board and a first dissipating surface of a dissipation board. The dissipation board is fitted into the housing. The printed-circuit board comprises at least one electronic component positioned in the dissipation chamber. The dissipation chamber further includes a filler in direct contact with a perimeter of the electronic component, with parts of the first surface of the printed-circuit board, with the tracks of the printed-circuit board, and with parts of the first dissipating surface of the dissipation board. The cabinet is configured so that a second dissipating surface of the dissipation board, opposite the first dissipating surface, is in direct contact with the external environment surrounding the cabinet.

### CROSS REFERENCE TO RELATED APPLICATION

This application claims foreign priority under 35 USC 119 to Brazilian application no. BR 20 2014032719-9 filed Dec. 26, 2014, and the disclosure of said Brazilian application is hereby expressly incorporated by reference into the present application.

1. Field

The present invention relates to an electronic device cabinet and to a dissipation board. More specifically, it relates to a cabinet on which a heat dissipation board is on direct contact with the environment surrounding the cabinet.

2. Background

Bearing in mind that the circuits used for controlling motors in general, including hermetic cooling compressors, employ electronic components that, upon managing the energy supplied to the equipment, exhibit losses that result in the generation of heat, there are various thermal coupling techniques that are used today to provide transfer of this undesired heat to the environment, thus preventing the overheating of the circuit, which might lead to damage and/or reduction of the useful life of the electronic components.

The better the thermal coupling between the parts, the better this transfer of heat between the electronic component where the losses are generated and the environment will be. Thus, the difference in temperature between the source of heat (electronic component with losses) and the environment, divided by the transferred-heat flow, represents the measurement of the coupling in Kelvin/Watt degrees.

One of these techniques to provide a good thermal coupling of the electronic component with the environment consists in installing the metallic elements that are thermally coupled to the electronic component, as for instance, flaps. This metallic element has the function of a heat sink and is provided with a large area exposed to the environment. In this way, it provides good thermal coupling between the parts, reducing significantly the rise in temperature of the electronic component when the latter releases heat due to the Joule effect cause by the losses.

In spite of being a quite effective and widespread form to promote thermal coupling, this technique requires fixation, for instance, by means of a screw, clip or equivalent, to provide physical coupling between the electronic component and the heat sink, which demands considerable physical space inside the equipment. Another disadvantage of this technique is that it requires much labor to mount each of the components on the heat sink, raising the cost of this mounting process.

Another technique used for transferring heat between the electronic component and the environment are the so-called “heat pipes” which use cooling fluids that transfer heat by change of phase. This is a very efficient way of transferring heat, but it requires a special construction for the heat sink that contains this cooling fluid, which makes it too expensive, besides requiring a geometric form and a physical space suitable for mounting the parts on each other.

According to document WO 9702729, coupling between the electronic components and the compressor carcass is known, the carcass region being close to the suction tubing for cooling gas that is at a quite reduced temperature, coming from the evaporator exit. In spite of facilitating the transfer of heat, this solution requires physical coupling between the electronic components and the compressor carcass, besides an efficient insulation, requiring the use of suitable devices for fixation and elaborate mounting solutions.

Document U.S. Pat. No. 5,060,114 describes the transfer of heat on an electronic device cabinet by the conduction effect. Thus, a conformable silicone pad is shaped to as to involve the electronic device cabinet, removing the heat generated by the latter. This configuration has the disadvantage of dissipating the heat generated by the set of electronic components only when the heat has already gone through the housing of this device cabinet, that it to say, the silicone pad is not in direct contact with the components, but rather with the housing that contains them. In this way, the batteries that prevent heat from coming out of contact with the components area increased.

Document U.S. Pat. No. 5,208,733 describes an enclosure that comprises a heat sink that supports a structural element. The heat sink is constituted by a metallic plate of considerable thickness, arranged over the electronic components. A layer of polymeric film is arranged by a vacuum process on the electronic components that are arranged on a printed-circuit board that, in turn, is fixed to the structural element.

A substance composed of silicone in the form of a gel is added to the enclosure so as to fill up the space between the metallic plate and the components. However, since this substance does not have characteristics of electric insulation, it does not come into direct contact with the electronic components or with the printed-circuit board, limiting itself to the contour delimited by the polymeric film. This construction requires various associated processes during the manufacture of this enclosure, increasing the cost thereof according to the need for much aggregated labor.

Another disadvantage is that, besides the thick metallic plate, the enclosure presents another protective layer, which makes it difficult to release the heat to the environment. In order to overcome this deficiency, one describes a cooling system and the presence of connectors, entailing ever greater increase in the costs and physical space occupied by the enclosure.

According to the foregoing, one does not know from the prior art an electronic device cabinet comprising a dissipation plate (board) that can be fixed without the need for tools and screws, and where the outer surface of the cabinet is formed by the dissipation board itself.

Additionally, one does not know from the prior art a dissipation board that is only engaged with the housing of an electronic device cabinet, said engagement being made without the use of adhesive materials.

Further, one not from the prior art a dissipation board having one of its surfaces facing the external environment surrounding an electronic device cabinet.

Further, the prior art does not disclose a dissipation board that protects physically a printed-circuit board arranged inside an electronic device cabinet.

Finally, the prior art does not disclose an electronic device cabinet provided with a dissipation board that has one of its surfaces in direct contact with the external environment surrounding the cabinet.

### SUMMARY

The present invention has the objective of providing an electronic device cabinet with its outer surface formed by a dissipation board.

It is also an objective of the present invention to provide a dissipation board that can be fixed without the need to use any fixation element or adhesive material.

An additional objective of the present invention is to provide a dissipation board having one of its surfaces directly exposed to the external environment surrounding the electronic device cabinet.

Further, the present invention has the objective of providing a dissipation board that will protect physically a printed-circuit board arranged inside the electronic device cabinet.

It is also an objective of the present invention to provide a dissipation board having one of its surfaces in direct contact with the external environment surrounding the electronic device cabinet.

An additional objective of the present invention consists of an electronic device cabinet in which the internal area of a dissipation chamber is delimited by a printed-circuit board and by a dissipation board.

The objectives of the present invention are achieved by means of an electronic device cabinet comprising an enclosure and a printed-circuit board with tracks, the printed-circuit board being positioned in the internal area of the housing and defining a dissipation chamber.

The dissipation chamber is formed between a first surface of the printed-circuit board and a first dissipating surface of a dissipation board.

The printed-circuit board further comprises at least one electronic component positioned in the dissipation chamber, the dissipation chamber further comprising a filler, the filler keeping direct contact with a perimeter of the electronic component, with parts of the first surface of the printed-circuit board, with the tracks of the printed-circuit board and with parts of the first dissipating surface of the dissipation board.

The electronic device cabinet is configured so that a second dissipating surface of the dissipation board opposite the first dissipating surface is in direct contact with the external environment surrounding the electronic device cabinet.

### BRIEF DESCRIPTION OF THE DRAWINGS

The present invention will now be described in greater detail with reference to an example of embodiment represented in the drawings. The figures show:

FIG. 1 is a sectional view of the electronic device cabinet proposed in the present invention;

FIG. 2 is an additional sectional view of the electronic device cabinet proposed in the present invention;

FIG. 3 is an additional sectional view of the electronic device cabinet proposed in the present invention.

### DETAILED DESCRIPTION

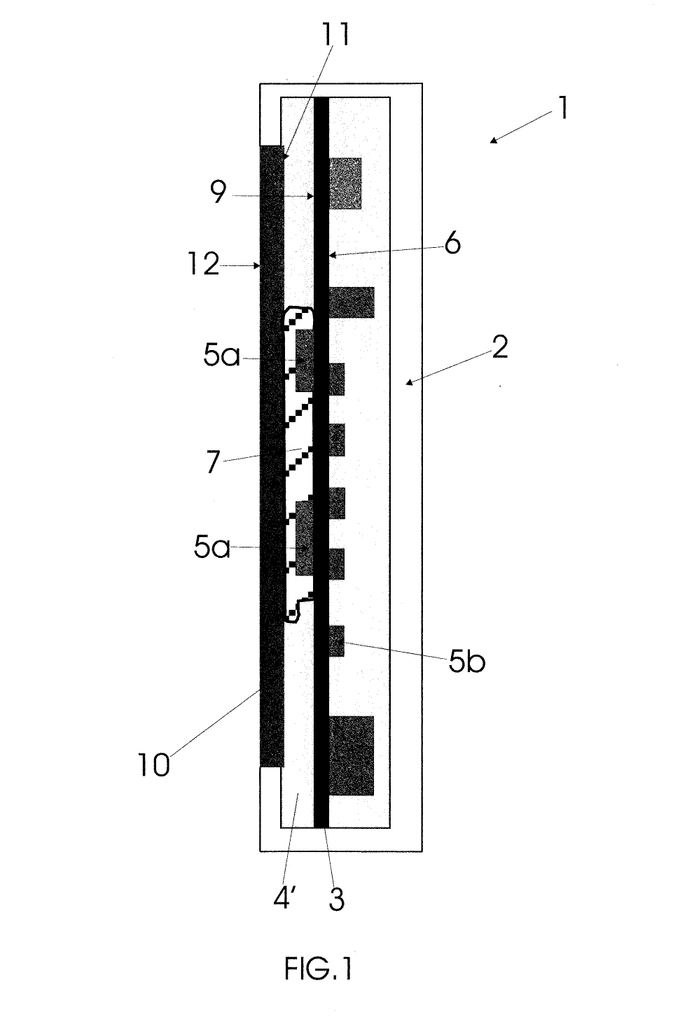

FIG. 1 is a sectional side representation of the electronic device cabinet 1 proposed in the present invention.

As one can observe, the electronic device cabinet 1 comprises a housing 2, provided with a printed-circuit board 3 with tracks. The printed-circuit board 3 is positioned inside the housing 2 and defines a dissipation chamber 4′.

Further, the printed-circuit board 3 comprises electronic components 5a and 5b, a filler 7 and a dissipation board 10.

The housing 2 is formed preferably by a rigid polymeric material and may take on various geometric forms. The polymeric material imparts to the housing 2 characteristics of electric insulation. The structural configuration for the housing 2 shown in FIG. 1 is only a preferred embodiment thereof and should not be regarded as being a limitation of the present invention.

The printed-circuit board 3 is positioned in the internal area of the housing 2, thus configuring a dissipation chamber 4′.

The dissipation chamber 4′ is formed between a first surface 9 of the printed-circuit board 3 and a first dissipating surface 11 of the dissipation board 10.

Further in the dissipation chamber 4′ are arranged the electronic components 5a, which are associated to the first surface 9 of the board 3. The board 3 further has electronic components 5b associated to a second surface 6 opposite the first surface 9.

The electronic components 5a are power electronic components and, due to their characteristics, they account for a relevant part of the heat dissipated in the circuit. This heat is the result of the Joule effect, present here due to the losses existing on the components.

As to the components 5b, they do not exhibit losses sufficient to generate a considerable amount of heat to the circuit. These components are associated to the second surface 6 of the board 3 opposite the surface 9 of the board 3.

The dissipation board 10 is constituted preferably by a metallic material, preferably aluminum, of thin thickness, for instance, preferably about 2 millimeters (mm) thick. Obviously, such a value should not be considered a limitation of the present invention, representing only a preferable aspect thereof.

Further, the use of the dissipation board 10 in the present invention has the objective of transferring the heat generated by the printed-circuit board 3 and by the electronic components 5a directly to the environment. Such board 10 should be preferably arranged at about 85% of the side of the cabinet 1.

It is important to note that, in the present invention, the heat is not transferred to one of the walls of the housing 2, but rather directly to the external environment surrounding the electronic device cabinet 1, as will be better described hereinafter.

In the present invention, the dissipation board 10 comprises a first dissipating surface 11 facing the first surface 9 of the electronic board 3, as can be seen in FIG. 1.

Further, the dissipation board 10 comprises a second dissipating surface 12 facing the external environment surrounding the cabinet 1. In other words, there are no barriers or elements between the second dissipating surface 12 and the external environment surrounding the cabinet 1.

Further, the second dissipating surface 12 of the dissipating board 10 is in direct contact with the external environment surrounding the electronic device.

By direct contact one understands that there is no barrier between the second dissipating surface 12 and the environment, that is to say, the second dissipating surface 12 operates as a protection to the printed-circuit board 3 and to the electronic components 5a.

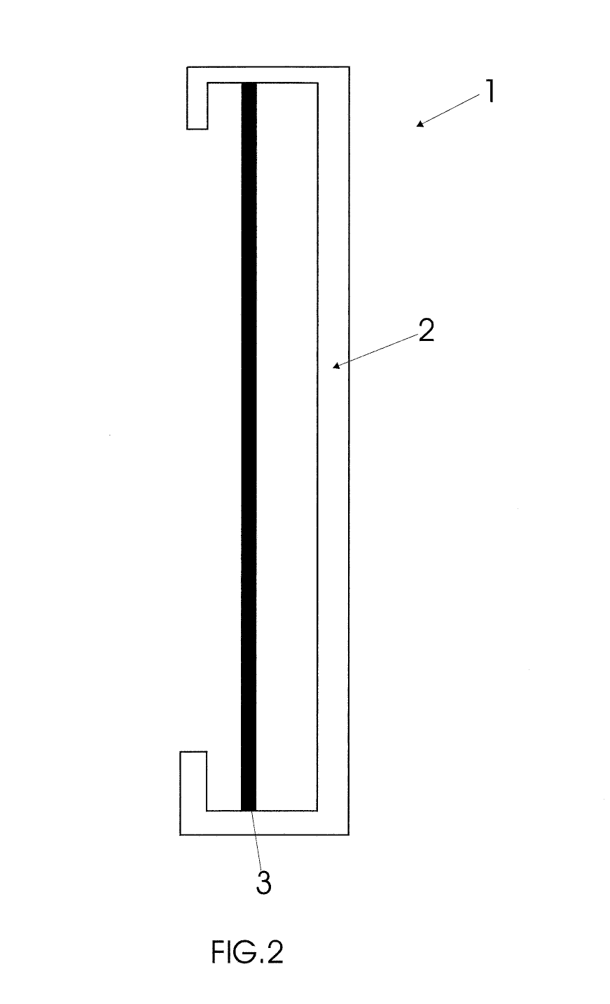

For a better understanding of the present invention, FIG. 2 is a sectional illustration only of the housing 2 and of the printed-circuit board 3. One observes the printed-circuit board 3 unprotected, since the dissipating board 10 is not associated to the housing 2.

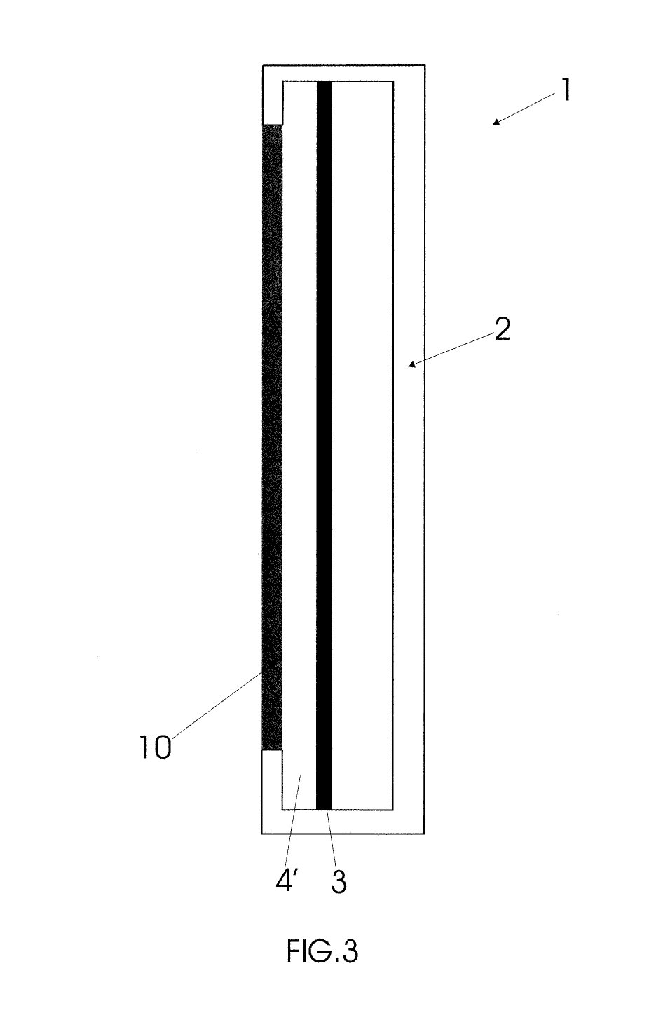

On the other hand, FIG. 3 illustrates the same elements represented in FIG. 2, but now with the dissipating board 10. In this figure, it is easier to notice that the dissipation board 10, when arranged, delimits, in conjunction with the printed-circuit board 3, the internal area of the dissipation chamber 4′. The association of the dissipation board 10 to the housing 2 is preferably made by fitting. So, the dissipation board 10 is arranged in the housing 2. For such association to take place in an effective manner, it is necessary that the length of the dissipation board 10 should be substantially equal to the length of the housing 2, in which it will be fitted.

It should be pointed out that, for fixation of the dissipation board 10, it is not necessary to use screws or any other fixation elements. Such board 10 is simply arranged in the housing 2.

With reference again to FIG. 1, one observes a filler 7 arranged inside the dissipation chamber 4′, simultaneously in contact with a perimeter of the electronic components 5a, parts of the first surface 9 of the board 3, where there are no associated electronic components, as for instance, the fillets or tracks of the printed circuit, and the dissipation board 10. The perimeters of the components 5a in contact with the filler 7 comprises the edges or portions of these components 5a that are above the surface 9 of the board 3.

The filler 7 is constituted by a gel, elastomer or electrically insulating paste, and may be of the polymeric type, either containing thermally conductive charges or not. The filler 7 should further be electrically insulating, since it is directly in contact with the tracks and terminals of the components of the printed circuit, where there are high voltages and generation of heat.

The filler 7 exhibits elasticity and/or plasticity sufficient to accommodate variation in dimensions due to thermal expansion undergone by the electronic components 5a, by the printed-circuit board 3 and by the housing 2.

This prevents the occurrence of cracks or the displacement of the filler material 7 with respect to the components 5a or to the tracks, from where heat should be removed, creating a clearance filled by air that makes it difficult for heat to pass. On the other hand, the filler 7 should not be very fluid, which presents it from pouring away and failing to fill the desired spaces.

When there are thermally conductive charges present, they are constituted by thermally conductive and electric insulating solid materials, in the form of powder or grains, such as aluminum oxide or oxide of any other metal. The granulation of this material depends only upon he process of producing the filler 7 and upon the physical stability desired for this filler 7 (more fluid or more solid). For this purpose, it is preferable to use the material in the form of a paste.

This filler 7 has electrically insulating properties, while conducting, in a very efficient manner, the heat dissipated by the power electronic components 5a and their terminals, as well as the heat generated by the tracks as far as the dissipation board 10. From the dissipation board 10, the heat passes directly to the environment without any barrier.

Finally, in order to prevent the risks of possible electric shocks, the electronic device cabinet 1 should be grounded in conformity with the international safety rules.

The present invention further relates to a dissipation board 10 of an electronic device cabinet 1, the electronic device cabinet 1 comprising a housing 2 provided with a printed-circuit board 3 with tracks and a filler 7.

The dissipation board 10 is arranged in a dissipation chamber 4′, formed between a first surface 9 of the printed-circuit board 3 with tracks, and a first dissipating surface 11 of the dissipation board 10.

The printed-circuit board 3 further comprises at least one electronic component 5a positioned in the dissipation chamber 4′, further parts of the dissipating surface 11 of the dissipation board 10 keep contact with the filler 7, the filler maintaining direct contact with a perimeter of the electronic component 5a, with parts of the first surface 9 of the printed-circuit board 3 and with the tracks of the printed-circuit board 3.

The dissipation board 10 further comprises a second dissipating surface 12 of the dissipation board 10, opposite the first dissipating surface 11, and in direct contact with the external environment surrounding the electronic device 1.

A preferred example of embodiment having been described, one should understand that the scope of the present invention embraces other possible variations, being limited only by the contents of the accompanying claims, which include the possible equivalents.

1. An electronic device cabinet (1) comprising a housing (2) and a printed-circuit board (3) with tracks, the printed-circuit board (3) being positioned in an internal area of the housing (2) and defining a dissipation chamber (4′);
the dissipation chamber (4′) being formed between a first surface (9) of the printed-circuit board (3) and a first dissipating surface (11) of a dissipation board (10),
the printed-circuit board (3) comprising at least one electronic component (5a) positioned in the dissipation chamber (4′),
the dissipation chamber (4′) keeping direct contact with a perimeter of the electronic component (5a), with parts of the first surface (9) of the printed-circuit board (3) with tracks of the printed-circuit board (3) and with parts of the first dissipating surface (11) of the dissipation board (10),
wherein a second dissipating surface (12) of the dissipation board (10), opposite to the first dissipating surface (11), is in direct contact with the external environment of the electronic device cabinet (1).

2. The electronic device cabinet (1) according to claim 1, wherein the dissipation board (10) is constituted by a metallic material.

3. The electronic device cabinet (1) according to claim 2, wherein the first dissipating surface (11) of the dissipation board (10) faces the printed-circuit board (3), and the second dissipating surface (12) faces the external environment surrounding the electronic device (1).

4. The electronic device cabinet (1) according to claim 3, wherein the dissipation board (10) is associated to the housing (2) by fitting.

5. The electronic device cabinet (1) according to claim 4, wherein the dissipation board (10) in conjunction with the printed-circuit board (3) delimits the internal area of the dissipation chamber (4′).

6. The electronic device cabinet (1) according to claim 1, wherein the filler (7) is directly in contact with terminals of the electronic component (5a).

7. The electronic device cabinet (1) according to claim 1, wherein the filler (7) comprises an electrically insulating paste.

8. The electronic device cabinet (1) according to claim 1, wherein the filler (7) comprises an electrically insulating elastomer.

9. The electronic device cabinet (1) according to claim 6, wherein the filler (7) comprises an additive or a charge of a thermally conductive material.

10. The electronic device cabinet (1) according to claim 7, wherein the filler (7) comprises an additive or a charge of a thermally conductive material.

11. The electronic device cabinet (1) according to claim 8, wherein the filler (7) comprises an additive or a charge of a thermally conductive material.

12. A dissipation board (10) of an electronic device cabinet (1), the electronic device cabinet (1) comprising a housing (2) provided with a printed-circuit board (3) with tracks and a filler (7),
the dissipation board (10) arranged in a dissipation chamber (4′) formed between a first surface (9) of the printed-circuit board (3) with tracks, and a first dissipating surface (11) of the dissipation board (10),
the printed-circuit board (3) further comprising at least one electronic component (5a) positioned in the dissipation chamber (4′),
parts of the first dissipating surface (11) of the dissipation board (10) in contact with the filler (7), the filler in direct contact with a perimeter of the electronic component (5a), with parts of the first surface (9) of the printed-circuit board (3) and with the tracks of the printed-circuit board (3),
wherein a second dissipating surface (12) of the dissipation board (10), opposite to the first dissipating surface (11), is in direct contact with the external environment surrounding the electronic device cabinet (1).

13. The dissipation board (10) according to claim 10, wherein said dissipation board is constituted by a metallic material.

14. The dissipation board (10) according to claim 11, wherein the first dissipating surface (11) faces the printed circuit (3), and the second dissipating surface (12) faces the external environment surrounding the electronic device cabinet (1).

15. The dissipation board (10) according to claim 12, wherein the latter is associated to the housing (2) by fitting.
